(19) United States
(12) Patent Application Publication
(10) Pub. No.: US 2026/0338646 A1
(43) Pub. Date: Oct. 29, 2026

(54) FOUP DEFECT INSPECTION METHOD AND DEVICE

(71) Applicant: ASIA NEO TECH INDUSTRIAL CO., LTD., TAOYUAN CITY (TW)

(72) Inventors: PU-CHANG YEH, TAOYUAN CITY (TW); YI-JUNG TZENG, TAOYUAN CITY (TW)

(21) Appl. No.: 19/578,723

(22) Filed: Mar. 25, 2026

Related U.S. Application Data
(60) Provisional application No. 63/793,179, filed on Apr. 23, 2025.

(51) Int. Cl. G01M 99/00; H10P 72/10

(52) U.S. Cl. CPC G01M 99/005; H10P 72/19

(57) ABSTRACT

A FOUP defect inspection method and device, applied in a cleaning area station of the FOUP, comprising performing unlocking and defect inspection of the FOUP on at least one load port. The unlocking comprises unlocking a door from a shell, and the defect inspection comprises detecting defective shells or doors with deformed shapes or structures, so as to shorten the cleaning operation time of the FOUP shell and door, and exclude the cleaning time occupied by defective products.

### BACKGROUND OF INVENTION

### 1. Field of the Invention

The present invention relates generally to a front-opening unified pod (FOUP), and particularly to a defect inspection method and device for the FOUP.

### 2. Description of Related Art

A front-opening unified pod (FOUP) is formed by a shell having a chamber, combined with a door in a locking manner. The FOUP can accommodate objects such as wafers, carriers, or panels in the chamber, facilitating the transport of the FOUP to multiple work stations by an OHT, enabling the necessary processing of the accommodated objects.

It is also known that, according to process requirements, the FOUP often needs to be filled with gases such as nitrogen (N₂) to maintain the process quality of the contained objects. After a period of use, the FOUP must be cleaned to remove harmful substances accumulated or remaining on the shell and door, thereby maintaining the production yield of the aforementioned process components during manufacturing. Such harmful substances include airborne particles, volatile organic compounds (VOCs), sulfur dioxide (SO₂), amines, acids, ammonia (NH₃), etc.

For this purpose, a cleaning area station is often added for the FOUP among the multiple processing stations arranged on the production line according to process requirements. Please refer to FIG. 1a, which discloses a prior art cleaning area station 200 specifically configured for cleaning the FOUP 10. The FOUP 10 can be automatically placed on at least one load port 280 of the cleaning area station 200 by being suspended and transported by the OHT. The load port 280 is configured for connecting the FOUP transported by the OHT into and out of the cleaning area station 200.

The cleaning area station 200 is usually equipped with a robot 270 having multi-axis movement capability, and surrounding the robot 270, there are multiple cleaning machines 220, 230, 240 for wet cleaning and vacuum drying purposes, and at least one unlocking station 250. At least one said inspection station 280 is located on one side of the cleaning machines 220, 230, 240. With this configuration, the robot 270 can grip and place the FOUP 10 from the inspection station 280, transport the FOUP 10 to the unlocking station 250 to unlock it into a separated state of shell 11 and door 12, and then transport the shell 11 and door 12 to the plurality of cleaning machines 220, 230, 240 for cleaning processes including wet cleaning and vacuum drying. The unlocking station 250 can also be used for locking the cleaned shell 11 and door 12 together to form the FOUP 10 again.

However, the above-mentioned prior art practice of arranging the unlocking station 250 within the cleaning area station 200 increases the operation time of the robot 270 in transporting the shell 11 and door 12 during the cleaning process, which is not conducive to improving the cleaning efficiency of the FOUP.

Please refer to FIG. 1b, which discloses a state where the shell 11 and door 12 of the FOUP 10 are separated after unlocking. The shell 11 has an opening 110, and a chamber 111 capable of accommodating a plurality of said objects is formed within the opening 110. A plurality of mutually corresponding guide ribs 112 arranged in rows are provided on both sides of the chamber 111. An outer wall on one side of the shell 11 is provided with a flange 113 (commonly known as a mushroom head) for gripping by an OHT. Additionally, a plurality of screws 114 are locked and held on the outer wall of the shell 11, and these screws 114 are used to secure the plurality of row-shaped guide ribs 112 within the opening 110. Furthermore, a sealing gasket 120 and row-shaped guide ribs 121 are provided on the periphery of an inner wall surface of the door 12. The function of the sealing gasket 120 is to provide a gas seal after the door 12 is closed and locked with the shell 11. The row-shaped guide ribs 121 on the door 12 and the row-shaped guide ribs 112 inside the shell 11 can correspond to each other in layers and are framed around the chamber 111, for guiding and holding objects such as wafers, carriers, or panels in layers. Additionally, please refer to FIG. 1c, which discloses that the bottom of the shell 11 has a pair of exhaust valve ports 13, a pair of inlet valve ports 14, and a plurality of screw holes 15 for screws to pass through and lock into the inner wall of the chamber, used for assembling screws to mount some functional components.

However, for the shell 11 and the door 12, after a period of use, the shell 11, the door 12, and their guide ribs 112, 121, etc., may develop defects such as skewing, deformation, or breakage. Furthermore, the sealing gasket 120 may also age or be damaged, causing defects in the FOUP 10. The aforementioned defects of the shell and the door must be identified and removed from the production line to ensure the normal usability of the FOUP.

In order to detect the above-mentioned defects of the FOUP 10 on the production line, the prior art has seen techniques that add defect inspection to the FOUP 10 cleaning process. Further, please refer to FIG. 1a, which discloses that an inspection station 260 is additionally installed in the aforementioned cleaning area station 20, used to detect the defective shell 11 and door 12.

In the above-mentioned prior art, arranging the inspection station 260 between the unlocking station 250 and the cleaning machines 220, 230, 240 also easily affects the operation time of the robot 270 in sequentially transporting the shell 11 and door 12 for unlocking, defect inspection, cleaning, and locking processes. Therefore, it is still not conducive to improving the cleaning efficiency of the FOUP, and all the above problems urgently need improvement.

### SUMMARY OF THE INVENTION

The objective of the present invention is to propose an improvement strategy focusing on the problem in existing cleaning area stations where the processes of unlocking and defect inspection of the FOUP increase the cleaning operation time of the FOUP.

A preferred embodiment of the present invention provides a FOUP defect inspection method, applicable in a cleaning area station of the FOUP. The cleaning area station comprises a load port for placing the FOUP, a plurality of cleaning machines for cleaning the FOUP, and a robot for transporting the FOUP between the load port and the plurality of cleaning machines. The FOUP is composed of a door locked onto a shell, and the shell and the door have a plurality of internal standard features. The inspection method comprises: unlocking the FOUP and opening the door on the shell, then detecting a plurality of internal current features of the shell and the door, and comparing differences between the internal current features and the internal standard features to determine a defect location of the FOUP; wherein the processes of unlocking the FOUP and detecting the shell and the door are both performed on the load port.

In a further implementation, the method of the present invention further comprises:

The internal standard features are constituted by at least one internal end surface standard image of the shell and the door, and the internal current features are respectively constituted by at least one internal end surface current image of the shell and the door. The load port unlocks the door on the shell by means of an unlocker, and detects the internal current features by means of at least one photosensitive coupling element.

The shell and the door further have a plurality of external standard features. The inspection method further comprises, before unlocking the FOUP, detecting a plurality of external current features of the shell and the door, and comparing differences between the external current features and the external standard features. Specifically, the external standard features are constituted by at least one external end surface standard image of the shell and the door, and the external current features are constituted by at least one external end surface current image of the shell and the door.

The load port unlocks the door on the shell by means of an unlocker, and detects the internal current features and the external current features by means of at least one photosensitive coupling element.

Specifically, the unlocker opens the door on the shell using one of a swinging movement and a linear movement. The photosensitive coupling element detects the external current features and the internal current features using at least one of a fixed manner and a movable manner.

The load port comprises at least one input port and at least one output port. The inspection method is performed on the input port, and the shell and the door are locked into the FOUP on the output port. Specifically, the output port locks the door onto the shell by means of a door closer, and the door closer opens the door on the shell using one of a swinging movement and a linear movement.

Further, to specifically implement the above method, another embodiment of the present invention provides a defect inspection device configurable in the cleaning area station of the FOUP. The load port in the cleaning area station has a table surface for placing the FOUP. The inspection device comprises an unlocker and at least one photosensitive coupling element. The unlocker has a pair of keys configured to be inserted into a pair of locking holes of the door, for unlocking the FOUP and opening the door on the shell. The at least one photosensitive coupling element is used for detecting a plurality of current features of the shell and the door. Specifically, the unlocker is disposed on one end side of the table surface of the load port, and the photosensitive coupling element is suspended around the table surface of the load port, for performing the unlocking, door opening and defect inspection on the FOUP by means of the load port before cleaning the FOUP.

In a further implementation, the device of the present invention further comprises:

The unlocker has a base capable of holding the door. The pair of keys protrude outward from a base surface of the base, and the base has a pivot portion. The base is pivotally connected to the end side of the table surface of the load port via the pivot portion, so that the base can insert the pair of keys into the pair of locking holes of the door in a swinging manner, to unlock and open the door on the shell. Specifically, the base can also be slidably assembled to the end side of the table surface of the load port via a linear slide rail, so that the base can insert the pair of keys into the pair of locking holes of the door in a linear movement manner, to unlock and open the door on the shell.

The photosensitive coupling element is suspended around the table surface of the load port using at least one of a fixed manner and a movable manner, for detecting the current features.

The load port is at least one input port for the FOUP. The cleaning area station further comprises at least one output port, and the output port locks the door onto the shell by means of a door closer to form the FOUP. Specifically, the door closer is disposed on one end side of a table surface of the output port. The door closer has a pair of keys configured to be inserted into a pair of locking holes of the door, for holding the door and locking the door onto the shell. Further, the door closer has a base capable of holding the door. The pair of keys protrude outward from a base surface of the base, and the base has a pivot portion. The base is pivotally connected to the end side of the table surface of the output port via the pivot portion, so that the base can insert the pair of keys into the pair of locking holes of the door in a swinging manner, to hold the door and lock the door onto the shell. Alternatively, the base is slidably assembled to the end side of the table surface of the output port via a linear slide rail, so that the base can insert the pair of keys into the pair of locking holes of the door in a linear movement manner, to hold the door and lock the door onto the shell.

Implemented in this way, and compared with the prior art, since the processes of unlocking the FOUP and detecting the shell and the door in the present invention are both performed on the load port, unlike the conventional processes where unlocking the FOUP and detecting the shell and the door are both performed inside the cleaning area station 20 shown in FIG. 1a using the robot 270 for transportation, the present invention thus achieves the following effects:
1. Saving the operation time of the robot 270 shown in FIG. 1a in sequentially transporting the shell 11 and door 12 for unlocking, defect inspection, cleaning, and locking processes.
2. Any shell 11 or door 12 identified as defective through defect inspection at the inspection station 280 shown in FIG. 1a can be directly removed by the OHT or other automated equipment to eliminate defective products from the production line, preventing the robot 270 in the cleaning area station 200 from picking up an already defective shell 11 or door 12 for cleaning, thereby improving the cleaning efficiency of non-defective products.

Further benefits and advantages of the present invention will become apparent after a careful reading of the detailed description with appropriate reference to the accompanying drawings.

### BRIEF DESCRIPTION OF THE DRAWINGS

FIG. 1a is a schematic top view of a conventional cleaning area station for a FOUP, illustrating that the cleaning area station is configured with a robot, cleaning machines, an unlocking station, an inspection station, and a load port.

FIG. 1b is an exploded perspective view of the FOUP shown in FIG. 1a after unlocking, illustrating that the article comprises a shell and a door.

FIG. 1c is a bottom view of the shell shown in FIG. 1b, illustrating that the bottom of the shell is configured with normally closed exhaust valve ports and inlet valve ports.

FIG. 2 is a schematic top view of disposing a defect inspection device in a FOUP cleaning area station according to the present invention, illustrating that the cleaning area station is configured with a robot, cleaning machines, and a load port, and that the load port is configured with an unlocker and a photosensitive coupling element constituting the defect inspection device.

FIG. 3 is a first type of schematic perspective view of the defect inspection device configured at the load port shown in FIG. 2, further illustrating the configuration of the unlocker and the photosensitive coupling element, wherein the unlocker includes a door opener and a door closer.

FIG. 4 is a schematic diagram of another configuration of the unlocker shown in FIG. 3.

FIG. 5 is a schematic diagram of the procedural steps for executing the FOUP defect inspection method according to the present invention.

FIG. 6 is a schematic perspective action diagram of the door opener shown in FIG. 3 covering the door, illustrating an aspect where the door opener swings to cover the door of the FOUP for unlocking.

FIG. 7 is a first type of schematic perspective action diagram of the door opener shown in FIG. 6 subsequently opening the door, illustrating an aspect where the door opener holds the door and swings back to a horizontal position, thereby opening the door on the shell, and allowing multiple photosensitive coupling elements to capture internal current features and external current features of the shell and the door.

FIG. 8 is another type of schematic perspective action diagram of the door opener shown in FIG. 7 opening the door, illustrating an aspect where the door opener holds the door and swings to a vertical position, thereby opening the door on the shell, and allowing multiple photosensitive coupling elements to capture internal current features and external current features of the shell and the door.

FIG. 9 is a schematic perspective view of the shell shown in FIG. 8 in another placement position, illustrating an aspect where the shell is rotated 180 degrees, allowing the photosensitive coupling element to capture an image of the outer wall surface on the back, as part of the external current features.

FIGS. 10-11 are schematic perspective views of the continuous action of the door closer shown in FIG. 3 performing door locking.

### DETAILED DESCRIPTION OF THE INVENTION

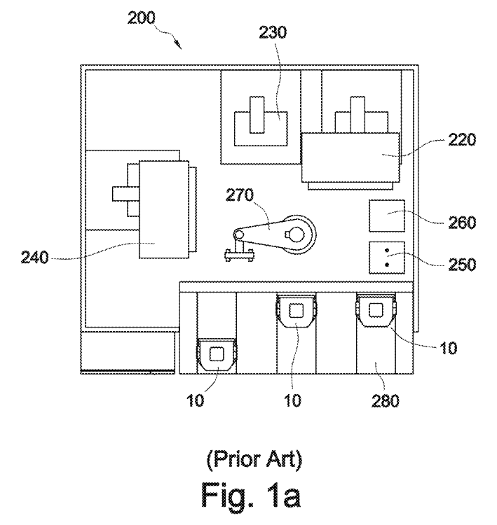

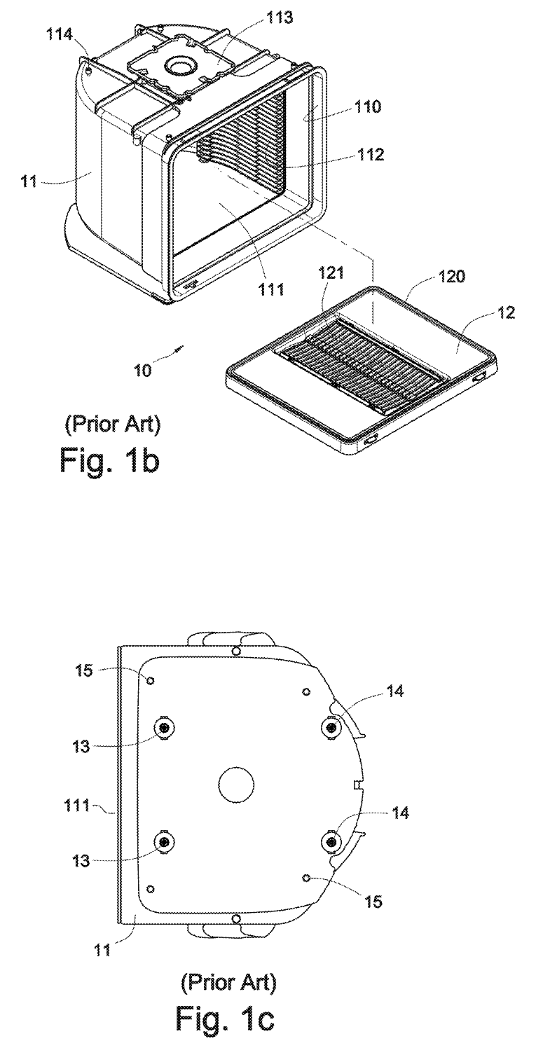

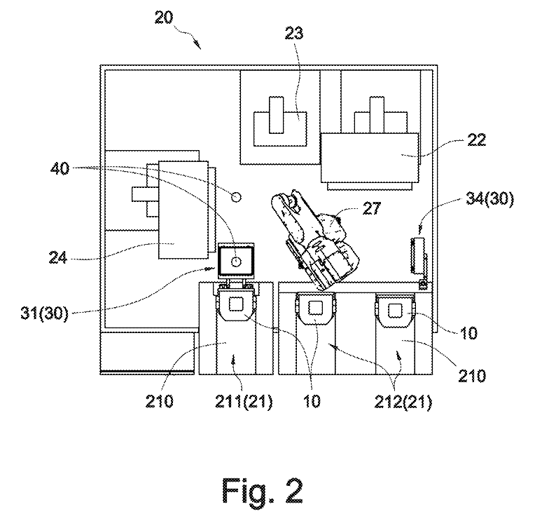

Firstly, please refer to FIG. 2, which discloses a defect inspection device provided by the present invention, configured to be placed in a cleaning area station 20 of the FOUP 10. The cleaning area station 20 shown in FIG. 2 includes a robot 27, a plurality of cleaning machines 22, 23, 24 arranged around the robot 27, and a load port 21 located on one side of the cleaning machines 22, 23, 24. Among them, the cleaning machines 22, 23, 24 can each be equipped with functions such as wet cleaning or vacuum drying; the robot 27 can be replaced by other automated equipment with multi-axis movement capability, used to transport the FOUP 10 between the load port 21 and the plurality of cleaning machines 22, 23, 24. Further, the FOUP 10 is in the form shown in FIG. 1b, i.e., composed of a shell 11 with a door 12 locked thereon; the load port 21 has a table surface 210 for placing the FOUP 10 that is still locked and integrated. The present invention can unlock the FOUP 10 at the load port 21 into the separated and independent shell 11 and door 12, and detect multiple current features (detailed later) of the shell 11 and the door 12. Subsequently, the robot 27 can sequentially retrieve the shell 11 and the door 12 with good current features from the load port 21, and transport them one by one to the plurality of cleaning machines 22, 23, 24 for cleaning processes such as wet cleaning and vacuum drying. Afterward, the robot 27 sequentially retrieves and transports the cleaned shell 11 and door 12 to the load port 21 to be combined and locked into the integrated FOUP 10, thereby completing the cleaning process of the FOUP 10.

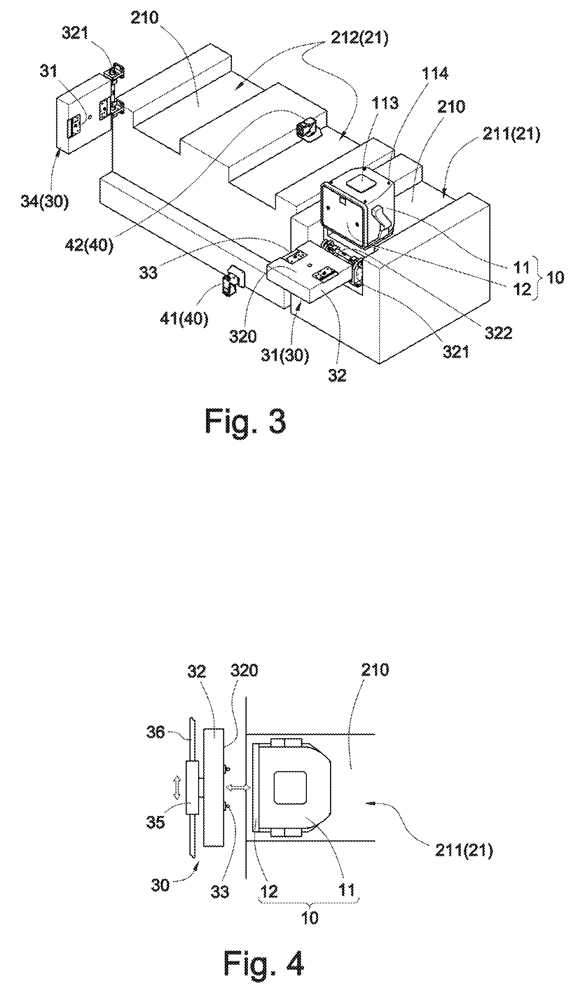

Please refer to FIG. 2 and FIG. 3 together for further explanation. The defect inspection device includes an unlocker 30 and at least one photosensitive coupling element 40 (CCD). The unlocker 30 has a pair of keys 33 inserted into the pair of locking holes of the door 12, used to unlock the FOUP 10 and open the door 12 on the shell 11; the photosensitive coupling element 40 is used to detect multiple current features of the shell 11 and the door 12. The unlocker 30 is configured on one end side of the table surface 210 of the load port 21, and the photosensitive coupling element 40 is suspended around the table surface 210 of the load port 21 by means of connections such as support rods or driving elements (not shown in the figure) used as fixed ends, to perform the processes of unlocking, opening the door, and defect inspection on the FOUP 10 via the load port 21 before cleaning the FOUP 10.

Further, FIG. 2 and FIG. 3 together disclose that the load port 21 may include an input port 211 and one or more output ports 212; the input port 211 is exclusively used by the OHT to transport the FOUP 10 to be cleaned and place it there, and the output port 212 is exclusively used by the robot 27 within the cleaning area station 20 to transport the cleaned FOUP 10 and place it there; the greater the number of input ports 211 and output ports 212, the more they can serve as temporary storage areas for the FOUP 10, to avoid waiting time for the OHT to place and the robot 27 to pick up. On the other hand, in a variant embodiment, only one load port 21 is needed, which simultaneously provides placement for FOUPs before and after cleaning. Although this is more time-consuming, it still falls within the applicable technical scope. In other words, the present invention is not limited by the load port 21 being for input, output, or simultaneously for input and output, nor by their quantity, and this is hereby clarified.

As shown in FIG. 3, the unlocker 30 has a base 32 capable of holding the door 12, and the pair of keys 33 protrudes outward from a base surface 320 of the base 32. When the load port 21 includes the input port 211 and the output port 212, the unlocker 30 can be divided into a door opener 31 installed on the end side of the table surface 210 of the input port 211, and a door closer 34 installed on the end side of the table surface 210 of the output port 212; wherein, the door opener 31 at the input port 211 is specifically responsible for unlocking and opening the door 12 on the shell 11, and the door closer 34 at the output port 212 has the same structure as the door opener 31 and is specifically responsible for driving the door 12 to lock and combine with the shell 11 to form the FOUP 10.

Further, the unlocker 30 shown in FIG. 3 is implemented in a swinging form. Specifically, the base 32 has a pivot portion 321, and at least one arm portion 322 connected between the pivot portion 321 and the base 32. The base 32 is pivotally connected to the end side of the table surface 210 of the load port 21 via the arm portion 322 and the pivot portion 321, so that the base 32 can pivot to insert the pair of keys 33 into the pair of locking holes of the door 12, unlocking and opening the door 12 on the shell 11.

Further, please refer to FIG. 4, which discloses implementation of the unlocker 30 in a rail-sliding form. Specifically, the base 32 can be configured on a slide carriage 35, and the slide carriage can be slidably configured on a linear slide rail 36, so that the slide carriage 35 can drive the base 32 to move biaxially (indicated by double-headed arrows in FIG. 4), and then positioned at the end side of the table surface 210 of the load port 21, enabling the base 32 to move biaxially and linearly to insert the pair of keys 33 into the pair of locking holes of the door 12, unlocking and opening the door 12 on the shell 11. Designs similar to this for unlocking and closing the door 12 all fall within the technically applicable scope of the present invention.

As shown in FIG. 3, it is disclosed that one or more photosensitive coupling elements 40 can be used, suspended around the table surface 210 of the load port 21 in at least one of a fixed or movable manner, to detect the current features. When there are multiple photosensitive coupling elements 40, they may include a first photosensitive coupling element 41 capable of imaging the position corresponding to the opening 110 of the shell 11 (as shown in FIG. 1b), and a second photosensitive coupling element 42 capable of imaging the outer wall surface of the door 12, or capable of imaging the outer wall surface of the door 12 and the top position (including the flange 113) of the shell 11, to detect the current features of the shell 11 and the door 12.

In the present invention, the current features of the shell 11 and the door 12 detected by the photosensitive coupling element 40 must be compared with a standard FOUP 10 to identify whether the FOUP 10 being inspected on the production line has defects.

Since the standard FOUP 10 itself has multiple standard features S in shape and structure, the multiple standard features S should include multiple internal standard features S1 and multiple external standard features S2 formed on the shell 11 and the door 12. Furthermore, the multiple internal standard features S1 construct the shape and structural contours of multiple inner wall surfaces of the shell 11 and the door 12, and the multiple external standard features S2 construct the shape and structural contours of multiple outer wall surfaces of the shell 11 and the door 12. In other words, the multiple internal standard features S1 and the multiple external standard features S2 together can construct a complete three-dimensional image of the inner and outer wall surfaces of the FOUP 10.

Correspondingly, the current features N of the FOUP 10 on the production line detected by the photosensitive coupling element 40 in the present invention should correspondingly include multiple internal current features N1 and multiple external current features N₂ presented by the inner and outer wall surfaces of the shell 11 and the door 12 being inspected on the production line. Specifically, the multiple internal current features N1 should be compared with the multiple internal standard features S1 to determine whether there are defects in the shape and contour of the inner wall surfaces of the inspected shell 11 and door 12; and, the multiple external current features N2 should be compared with the multiple external standard features S2 to determine whether there are defects in the shape and contour of the outer wall surfaces of the inspected shell 11 and door 12.

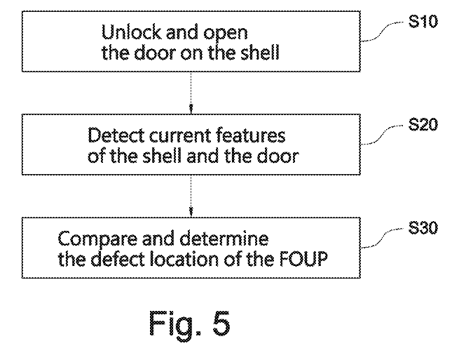

Please refer to FIG. 5, which discloses that the present invention can execute a FOUP defect inspection method based on the above-mentioned FOUP defect inspection device configured on the production line, including sequentially executing the following Step S10 to Step S30.

Step S10: Unlock and open the door on the shell

This step takes the configuration shown in FIG. 3 as an example to illustrate unlocking and opening the door 12 on the shell 11 by means of the door opener 31 (or unlocker 30) configured on the end side of the table surface 210 of the input port 211. Specifically, when the OHT transports the FOUP 10 to be cleaned on the production line to the input port 211 (or load port 21) and places it (as shown in FIG. 3), the outer wall surface of the door 12 is exposed facing the base 32 of the door opener 31. In the example shown in FIG. 3, the base 32 of the door opener 31 is placed horizontally, so that the base surface 320 faces upward, exposing the pair of keys 33.

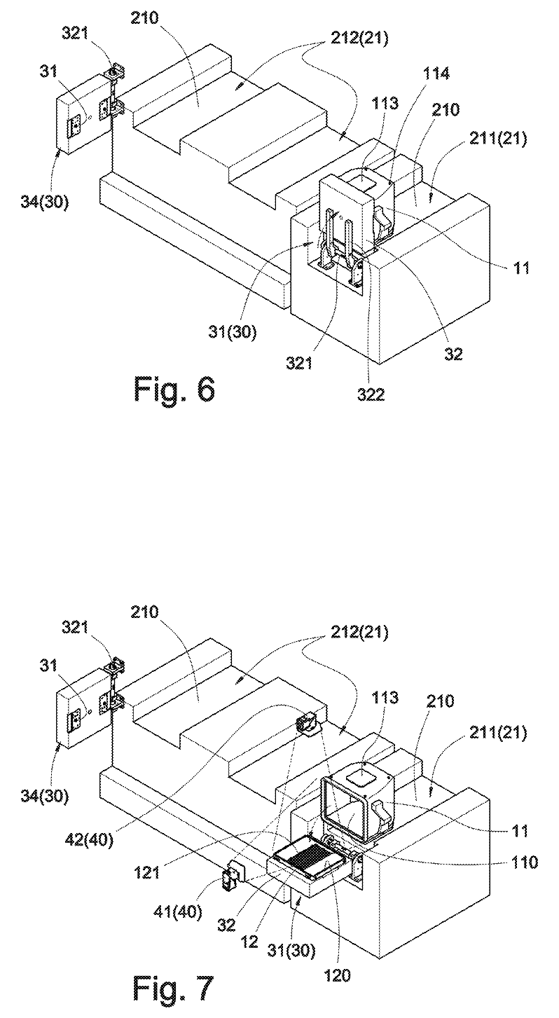

Please refer to FIG. 6, which discloses that the horizontally placed base 32 of the door opener 31 described in FIG. 3 swings toward the door 12 via the arm portion 322 and the pivot portion 321, so that the base surface 320 shown in FIG. 3 covers the outer wall surface of the door 12, and the pair of keys 33 are inserted into the pair of locking holes of the door 12 to unlock the door 12.

Please refer to FIG. 7, which discloses that the base 32 in FIG. 6 holds the door 12 by means of the pair of keys 33 shown in FIG. 3, so that the door 12 follows the resetting swing of the base 32 back to the horizontal original position, thereby detaching from the shell 11, and exposing the inner wall surface of the door 12 configured with the sealing gasket 120 and row-shaped guide ribs 121 facing upward, thus completing the opening of the door 12 on the shell 11.

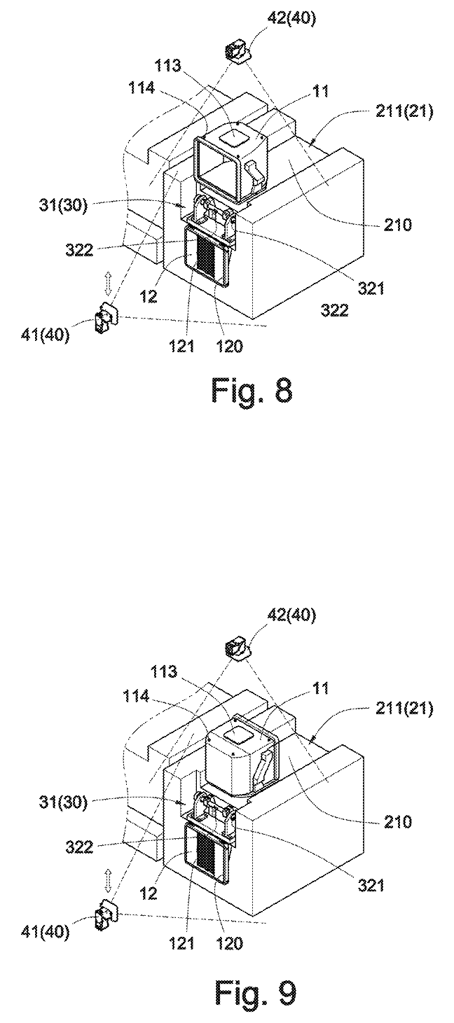

Further, please refer to FIG. 8, which discloses that the base 32 of the door opener 31 can drive the door 12 via the arm portion 322 and the pivot portion 321 to swing to a vertical state (not the horizontal state shown in FIG. 7), so that the inner wall surface of the door 12 configured with the sealing gasket 120 and row-shaped guide ribs 121 can be exposed outward, thus completing the opening of the door 12 on the shell 11.

Step S20: Detect current features of the shell and the door

As shown in FIG. 7 and FIG. 8, this step detects the current features of the shell 11 and the door 12 by means of one or more photosensitive coupling elements 40 suspended around the table surface 210 of the input port 211 (or load port 21). Specifically, when the load port 21 is divided into the input port 211 and the output port 212, the photosensitive coupling element 40 is suspended at the input port 211; when the load port 21 simultaneously has both input and output functions, the photosensitive coupling element 40 is suspended at the load port 21.

In the example shown in FIG. 7, when the photosensitive coupling element 40 includes the first photosensitive coupling element 41 and the second photosensitive coupling element 42, the fixed first photosensitive coupling element 41 can correspond to the position of the opening 110 of the shell 11 to capture an image of the inner wall surface of the shell 11 having the internal guide ribs 112, and the second photosensitive coupling element 42, which is linearly movable in the horizontal direction, can be moved to a position corresponding to the inner wall surface of the door 12 configured with the sealing gasket 120 and the row-shaped guide ribs 121 to capture an image, collectively serving as the internal current features N1 of the inspected FOUP 10. At the same time, the second photosensitive coupling element 42 can also be moved to a position corresponding to the top area of the shell 11 including the flange 113 to capture an image, serving as the external current features N2 of the inspected FOUP 10.

Further, in the example shown in FIG. 7, besides being implemented in a fixed manner, the first photosensitive coupling element 41 can also be implemented in a manner of linear movement in the horizontal direction. The internal current features N1 of the FOUP 10 may also include an image captured by the first photosensitive coupling element 41 corresponding to the edge position of the door 12, capturing the sidewall of the door 12 combined with the side of the sealing gasket 120, to determine whether the sealing gasket 120 is damaged or detached. Also, in the example shown in FIG. 7, the external current features N2 may also include, in the state of FIG. 3, an image of the outer wall surface of the door 12 having the pair of locking holes captured by the first photosensitive coupling element 41, which together with the image of the top area of the shell 11 including the flange 113 serves as the external current features N2 of the inspected FOUP 10.

In the example shown in FIG. 8, when the photosensitive coupling element 40 includes the first photosensitive coupling element 41 and the second photosensitive coupling element 42, the first photosensitive coupling element 41 can sequentially correspond to the position of the opening 110 of the shell 11 to capture an image of the inner wall surface of the shell 11 having the internal guide ribs 112, and capture an image of the inner wall surface of the door 12 configured with the sealing gasket 120 and the row-shaped guide ribs 121, collectively serving as the internal current features N1 of the inspected FOUP 10. At the same time, the movable or fixed second photosensitive coupling element 42 can correspond to the top area of the shell 11 including the flange 113 to capture an image, serving as the external current features N2 of the inspected FOUP 10. Similarly, in the example shown in FIG. 8, the external current features N2 may also include, in the state of FIG. 3, an image of the outer wall surface of the door 12 having the pair of locking holes captured by the first photosensitive coupling element 41, which together with the image of the top area of the shell 11 including the flange 113 and the screws 114 serves as the external current features N2 of the inspected FOUP 10.

Please refer to FIG. 9, which discloses that the shell 11 placed on the table surface 210 of the input port 211 with the door 12 already opened (as in FIG. 8) can be rotated 180 degrees by means of an additional rotating table (not shown in the figure) configured on the table surface 210, or by means of the robot 27 in the cleaning area station 20, to drive or move the shell 11, allowing the first photosensitive coupling element 41 to capture an image of the outer wall surface 41 on the back of the shell 11 (as in FIG. 9) as part of the external current features N2 of the inspected FOUP 10. This also falls within the scope of additional applications of the present invention.

Further, in a variant embodiment, the present invention may first detect multiple external current features N2 of the shell 11 and the door 12 according to the above method before unlocking the FOUP 10, and compare the differences between the external current features N2 and the external standard features S2, and then unlock and open the door 12 on the shell 11, detect multiple internal current features N1 of the shell 11 and the door 12, and compare the differences between the internal current features N1 and the internal standard features S1.

Step S30: Compare and determine the defect location of the FOUP

This step uses a control unit (which can be made of MCU, not shown in the figure) configured in the device body, internally storing the standard features S (including internal standard features S1 and external standard features S2) of the shell 11 and the door 12, and the control unit receives the current features N (including internal current features N1 and external current features N2) detected in Step S20 above, and then compares whether there are differences in the image features between the standard features S and the current features N. When there is an error in the image features that exceeds a predetermined allowable range, the position where the error exists is determined as the defect location of the FOUP 10, and it is confirmed whether the defect location is on the inner wall surface or/and the outer wall surface of the shell 11 or/and the door 12, to complete the FOUP defect inspection process of the present invention.

Since the execution processes of Step S10 to Step S30 above are all performed at the load port 21 (or input port 211), and the robot 27 in the cleaning area station 20 is only responsible for transporting the unlocked and inspected shell 11 and door 12 sequentially into and out of the cleaning machines 22, 23, 24 for cleaning processes such as wet cleaning and vacuum drying, the execution process of the present invention significantly reduces the operating time for the robot 27 in the cleaning area station 20 to transport the shell 11 and door 12 for sequential cleaning. Furthermore, a shell 11 or door 12 determined to be defective through defect inspection at the load port 21 (or input port 211) can be directly removed by the OHT or other automated equipment, eliminating defective items from the production line, and preventing the robot 27 in the cleaning area station 20 from picking up an already defective shell 11 or door 12 for cleaning, thus greatly improving the operational efficiency of cleaning FOUPs while detecting defective items.

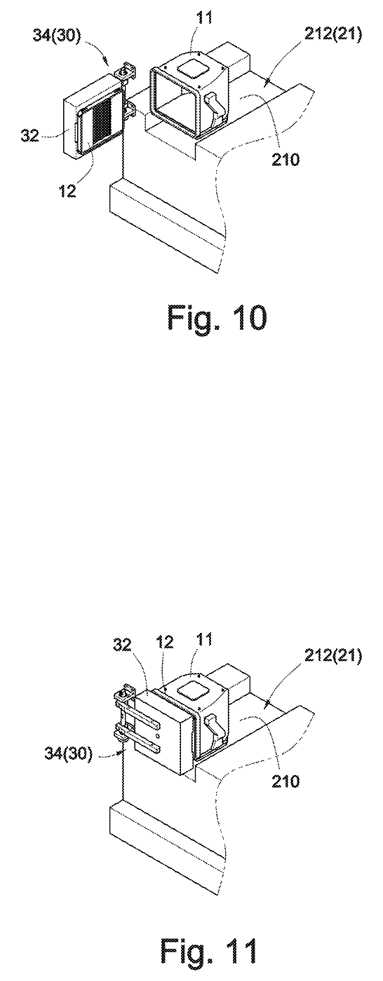

Please refer to FIG. 10 to FIG. 11 in sequence, which disclose that the cleaned shell 11 can be transported by the robot 27 in the cleaning area station 20 shown in FIG. 2 to be placed on the table surface 210 of the output port 212 (as in FIG. 10), and the robot 27 can also move the cleaned door 12 to a position where the door 12 can be held by the door closer 34 (as in FIG. 10). Subsequently, the door closer 34 drives the door 12 to lock onto the shell 11 (as in FIG. 11). Thus, the assembly of the cleaned good FOUP 10 is completed, facilitating the OHT to transport the FOUP 10 away from the cleaning area station 20.

In a variant embodiment, the execution process of Step S20 to Step S30 above can alternatively be performed at the output port 212. This includes, before the door closer 34 drives the door 12 to lock onto the shell 11, first using the aforementioned photosensitive coupling element 40 (including the first photosensitive coupling element 41 and the second photosensitive coupling element 42) to execute Step S20, i.e., detecting the current features N (including internal current features N1 and external current features N2) of the cleaned shell 11 and the door 12. Subsequently, the control unit executes the aforementioned Step S30, i.e., comparing and determining the defect location of the FOUP, thus completing the FOUP defect inspection process of the present invention. Thereafter, the door closer 34 drives the door 12 to lock onto the shell 11 (as in FIG. 11), thus completing the assembly of the cleaned FOUP 10. Accordingly, the OHT or other automated equipment can automatically identify whether the FOUP 10 on the output port 212 is good or defective, and then transport it to an appropriate location respectively, allowing the FOUP 10 to leave the cleaning area station 20.

Although the invention has been explained in relation to its preferred embodiment, it is to be understood that many other possible modifications and variations can be made without departing from the spirit and scope of the invention as hereinafter claimed.

1. A FOUP defect inspection method, applied in a cleaning area station of the FOUP, the cleaning area station comprising a load port for placing the FOUP, a plurality of cleaning machines for cleaning the FOUP, and a robot for transporting the FOUP between the load port and the plurality of cleaning machines, the FOUP being composed of a door locked onto a shell, and the shell and the door having a plurality of internal standard features, the inspection method comprising:
unlocking the FOUP and opening the door on the shell, then detecting a plurality of internal current features of the shell and the door, and comparing differences between the internal current features and the internal standard features to determine a defect location of the FOUP;
wherein the processes of unlocking the FOUP and detecting the shell and the door are both performed on the load port.

2. The FOUP defect inspection method defined in claim 1, wherein the internal standard features are constituted by at least one internal end surface standard image of the shell and the door, and the internal current features are respectively constituted by at least one internal end surface current image of the shell and the door.

3. The FOUP defect inspection method defined in claim 1, wherein the shell and the door further have a plurality of external standard features, the inspection method further comprising, before unlocking the FOUP, detecting a plurality of external current features of the shell and the door, and comparing differences between the external current features and the external standard features.

4. The FOUP defect inspection method defined in claim 3, wherein the external standard features are constituted by at least one external end surface standard image of the shell and the door, and the external current features are constituted by at least one external end surface current image of the shell and the door.

5. The FOUP defect inspection method defined in claim 3, wherein the load port unlocks the door on the shell by means of an unlocker, and detects the internal current features and the external current features by means of at least one photosensitive coupling element.

6. The FOUP defect inspection method defined in claim 5, wherein the unlocker opens the door on the shell using one of a swinging movement and a linear movement.

7. The FOUP defect inspection method defined in claim 5, wherein the photosensitive coupling element detects the external current features and the internal current features using at least one of a fixed manner and a movable manner.

8. The FOUP defect inspection method defined in claim 5, wherein the load port comprises at least one input port and at least one output port, the inspection method is performed on the input port, and the shell and the door are locked together to form the FOUP on the output port.

9. The FOUP defect inspection method defined in claim 8, wherein a door closer locks the door onto the shell at the output port, and the door closer opens the door on the shell using one of a swinging movement and a linear movement.

10. A FOUP defect inspection device, configured in a cleaning area station of the FOUP, the cleaning area station comprising a load port for placing the FOUP, a plurality of cleaning machines for cleaning the FOUP, and a robot for transporting the FOUP between the load port and the plurality of cleaning machines, the load port having a table surface for placing the FOUP, the FOUP being composed of a door locked onto a shell, the inspection device comprising:
an unlocker, having a pair of keys configured to be inserted into a pair of locking holes of the door, for unlocking the FOUP and opening the door on the shell; and
at least one photosensitive coupling element, for detecting a plurality of current features of the shell and the door;
wherein the unlocker is disposed on one end side of the table surface of the load port, and the photosensitive coupling element is suspended around the table surface of the load port, the unlocker being configured for performing the unlocking, door opening and defect inspection on the FOUP at the load port before cleaning the FOUP.

11. The FOUP defect inspection device defined in claim 10, wherein the unlocker has a base capable of holding the door, the pair of keys protrude outward from a base surface of the base, and the base has a pivot portion, the base is pivotally connected to the end side of the table surface of the load port via the pivot portion, so that the base can insert the pair of keys into the pair of locking holes of the door in a swinging manner, to unlock and open the door on the shell.

12. The FOUP defect inspection device defined in claim 10, wherein the unlocker has a base capable of holding the door, the pair of keys protrude outward from a base surface of the base, and the base is slidably assembled to the end side of the table surface of the load port via a linear slide rail, so that the base can insert the pair of keys into the pair of locking holes of the door in a linear movement manner, to unlock and open the door on the shell.

13. The FOUP defect inspection device defined in claim 10, wherein the photosensitive coupling element is suspended around the table surface of the load port using at least one of a fixed manner and a movable manner, for detecting the current features.

14. The FOUP defect inspection device defined in claim 10, wherein the load port is at least one input port for the FOUP, the cleaning area station further comprises at least one output port, and the output port locks the door onto the shell by means of a door closer to form the FOUP.

15. The FOUP defect inspection device defined in claim 14, wherein the door closer is disposed on one end side of a table surface of the output port, the door closer has a pair of keys configured to be inserted into a pair of locking holes of the door, for holding the door and locking the door onto the shell.

16. The FOUP defect inspection device defined in claim 15, wherein the door closer has a base capable of holding the door, the pair of keys protrude outward from a base surface of the base, and the base has a pivot portion, the base is pivotally connected to the end side of the table surface of the output port via the pivot portion, so that the base can insert the pair of keys into the pair of locking holes of the door in a swinging manner, to hold the door and lock the door onto the shell.

17. The FOUP defect inspection device defined in claim 15, wherein the door closer has a base capable of holding the door, the pair of keys protrude outward from a base surface of the base, and the base is slidably assembled to the end side of the table surface of the output port via a linear slide rail, so that the base can insert the pair of keys into the pair of locking holes of the door in a linear movement manner, to hold the door and lock the door onto the shell.
